(19) United States
(12) Patent Application Publication
(10) Pub. No.: US 2025/0292994 A1
(43) Pub. Date: Sep. 18, 2025

(54) GRID-LESS ION ENERGY DETECTOR

(71) Applicant: Tokyo Electron Limited, Tokyo (JP)

(72) Inventors: Zhiying Chen, Austin, TX (US); Peter Lowell George Ventzek, Austin, TX (US); Michael Hummel, Austin, TX (US); Megan Carruth, Austin, TX (US); Joel Blakeney, Austin, TX (US); Shyam Sridhar, Austin, TX (US)

(21) Appl. No.: 18/606,289

(22) Filed: Mar. 15, 2024

(51) Int. Cl. H01J 37/244; H01J 37/147; H01J 37/32

(52) U.S. Cl. CPC H01J 37/244; H01J 37/1472; H01J 37/32651; H01J 37/32926; H01J 37/32935; H01J 37/3299; H01J 2237/24405; H01J 2237/24585; H01J 2237/3321; H01J 2237/3348

(57) ABSTRACT

An ion energy detector includes an ion shield that includes an aperture configured to produce an ion beam from incident ions, an ion collector disposed in a fixed position behind the ion shield, and an ion deflector that includes a pair of parallel plates disposed behind the ion shield. The ion beam travels behind the ion shield along an axis of the aperture. The ion collector is offset from the axis of the aperture. The pair of parallel plates are configured to generate an electric field to deflect the ion beam off the axis and toward the ion collector. The ion energy detector may be included in a detection system and be in physical contact with a substrate, such as on or embedded in the substrate. The ion shield may include an outer surface that has the same electric potential as the substrate.

### TECHNICAL FIELD

The present invention relates generally to ion detectors for plasma characterization, and, in particular embodiments, to apparatuses, systems, and methods for the detection of ion energy and related properties of a plasma.

### BACKGROUND

Generally, a semiconductor device, such as an integrated circuit (IC) is fabricated by sequentially depositing and patterning layers of dielectric, conductive, and semiconductor materials over a substrate to form a network of electronic components and interconnect elements (e.g., transistors, resistors, capacitors, metal lines, contacts, and vias) integrated in a monolithic structure. Many of the processing steps used to form the constituent structures of semiconductor devices are performed using plasma processes. Many plasma processing techniques exist, including chemical dry etching (CDE) (e.g., plasma ashing), physical or sputter etching, reactive ion etching (RIE), plasma-enhanced chemical vapor deposition (PE-CVD), plasma-enhanced atomic layer etch (PE-ALE), atomic layer deposition (PE-ALD), and others.

The minimum feature sizes of semiconductor devices continue to shrink at each successive technology node to reduce cost (e.g., by roughly doubling the component packing density). The demand for low cost electronics with high functionality has driven innovations in patterning complex three-dimensional (3D) device structures with feature sizes down to a few nanometers. With lateral dimensions approaching the scale of molecules and atoms, plasma technology faces the challenge of fabricating very high aspect ratio structures with processes that can also meet the stringent precision, uniformity, stability, and repeatability required for IC manufacturing. An increasing number of IC designs, such as nonvolatile flash memory (NVM) and dynamic random-access memory (DRAM), are adopting high density 3D structures for volume manufacturing that may require precise control, at almost atomic dimensions. Plasma processes such as high aspect ratio contact (HARC) etching and PE-ALE are sensitive to kinetic energy and direction of ions during processing and the precision of the etch process rely on a narrow distribution of ion energy and ion angle. Precise measurements of these plasma properties are desirable to optimize and enable these plasma processes. Further innovations in the detectors and detection methods for ion energy distribution (IED) and ion angular distribution (IAD) remain to be made.

### SUMMARY

In accordance with an embodiment of the invention, an ion energy detector includes an ion shield that includes an aperture configured to produce an ion beam from incident ions, an ion collector disposed in a fixed position behind the ion shield, and an ion deflector that includes a pair of parallel plates disposed behind the ion shield. The ion beam travels behind the ion shield along an axis of the aperture. The ion collector is offset from the axis of the aperture. The pair of parallel plates are configured to generate an electric field to deflect the ion beam off the axis of the aperture and toward the ion collector.

In accordance with another embodiment of the invention, an ion energy detection system includes a substrate, and an ion energy detector in physical contact with the substrate. The ion energy detector includes an enclosure with an ion shield that includes an outer shield surface and an aperture configured to produce an ion beam from incident ions, an ion collector disposed in a fixed position in the enclosure, and an ion deflector including a pair of parallel plates disposed in the enclosure. The outer shield surface having the same electric potential as the substrate. The ion beam travels behind the ion shield along an axis of the aperture. The ion collector is offset from the axis of the aperture. The pair of parallel plates are configured to generate an electric field to deflect the ion beam off the axis of the aperture and toward the ion collector.

In accordance with still another embodiment of the invention, a plasma system includes a chamber configured to contain a plasma, a substrate disposed in the chamber, and an ion energy detector in physical contact with the substrate. The ion energy detector includes an enclosure with an ion shield that includes an outer shield surface and an aperture configured to produce an ion beam from the plasma, an ion collector disposed in a fixed position in the enclosure, and an ion deflector including a pair of parallel plates disposed in the enclosure. The outer shield surface has the same electric potential as the substrate. The ion beam travels behind the ion shield along an axis of the aperture. The ion collector is offset from the axis of the aperture. The plasma system also includes a controller operatively coupled to the ion energy detector. The controller includes a processor and a non-transitory computer-readable medium storing a program including instructions that, when executed by the processor, perform a method of measuring ion energy of the plasma. The method includes applying a voltage difference between the pair of parallel plates to generate an electric field deflecting the ion beam off the axis of the aperture and toward the ion collector, measuring ion flux from the ion beam deflected by the voltage difference, and obtaining ion energy of ions of the ion flux by scaling the voltage difference with a constant value.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates an example ion energy detector that uses an ion deflector with a pair of parallel plates to enable grid-less detection of ion energy at a fixed ion collector in accordance with embodiments of the invention;

FIG. 2 illustrates an example ion energy detector that includes a front plate with a grounded conductive surface and an ion deflector with a pair of parallel plates to enable grid-less detection of ion energy at a fixed Faraday cup in accordance with embodiments of the invention;

FIG. 3 illustrates an example ion energy detection system that includes a grid-less ion energy detector disposed on a substrate where the ion energy detector has a conductive front surface at the same electric potential as the substrate surface in accordance with embodiments of the invention;

FIG. 4 illustrates an example ion energy detection system that includes an array of grid-less ion energy detectors embedded in a substrate in accordance with embodiments of the invention;

FIG. 5 illustrates an example ion energy detection system that includes an array of grid-less ion energy detectors with ion apertures of different aspect ratios embedded in a substrate in accordance with embodiments of the invention;

FIG. 6 illustrates an example ion energy detection system that includes an array of grid-less ion energy detectors with ion apertures of different shapes embedded in a substrate in accordance with embodiments of the invention;

FIG. 7 illustrates an overhead view of an example ion energy detection system that includes an array of ion energy detectors embedded in a substrate in accordance with embodiments of the invention;

FIG. 8 illustrates an example plasma system that includes one or more grid-less ion energy detectors and may be used to perform methods of measuring ion energy of a plasma in accordance with embodiments of the invention;

FIG. 9 illustrates a flowchart of an example method of process optimization using one or more grid-less ion energy detectors in accordance with embodiments of the invention; and

FIG. 10 illustrates an example method of measuring ion energy of a plasma in accordance with embodiments of the invention.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope. Unless specified otherwise, the expressions “around”, “approximately”, and “substantially” signify within 10%, and preferably within 5% of the given value or, such as in the case of substantially zero, less than 10% and preferably less than 5% of a comparable quantity.

Detecting the IED (ion energy distribution) of a plasma is typically achieved using a series of grids that ions pass through before reaching a detector. The use of grids for ion energy detection has various drawbacks, which include arcing and sputter damage as well as increased complexity (due to fabrication, alignment, etc.). The applied voltage to the grids is increased in order to discriminate between higher ion energies. However, the increased voltage on the grids also worsens the undesirable arcing and sputtering effects. As a result, conventional ion energy detectors have an upper limit on detectable ion energy (e.g., well below 10 keV).

Control of the IED is desirable for many plasma processes and becomes more and more important as the size of the features decreases (e.g., in the range of nanometers, such as 3 nm and lower). For example, etching processes, such as HARC etching and PE-ALE are highly sensitive to both ion energy and ion angle. For high-aspect-ratio dynamic random-access memory (DRAM) and 3D NAND etching process, ions with high energy may be used (e.g., in the range of about 10 keV-15 keV). However, for at least the above reasons, diagnostics of high energy ions cannot be achieved by conventional ion energy detectors.

In accordance with embodiments herein described, the invention proposes a grid-less ion energy detector. Specifically, the ion energy detector is grid-less in the sense that ions incident on the ion energy detector (e.g., from a plasma) travel unobstructed to an ion collector. In various embodiments, an ion energy detector includes a structure configured to produce an ion beam from the incident ions (e.g., an ion shield comprising an aperture) that travels through a pair of parallel plates configured as an ion deflector, and to an ion collector in a fixed position off the axis of the ion beam. An electric field is generated between the pair of parallel plates to deflect the ion beam.

The embodiment ion energy detectors described herein may have various advantages over conventional ion energy detectors. One possible benefit of the embodiment ion energy detectors over conventional ion energy detectors is the ability to continuously measure a broad range of ion energies from near 0 eV up to and exceeding 15 keV. Measurements may also be made directly (i.e., without taking a derivative of the signal) and quickly, allowing time-resolved IED measurements with a resolution on the order of hundreds of nanoseconds. Additionally, the embodiment ion energy detectors may have the advantage of being scalable so that ion energy and flux measurements can be made at the substrate level. Further, ion energy and related properties may also be measured at various locations on a substrate using arrays of ion energy detectors, whether at the substrate surface or embedded within the substrate. Variation of aperture attributes (such as aspect ratio and shape) can also be leveraged to beneficially provide ion conductance and/or phase information.

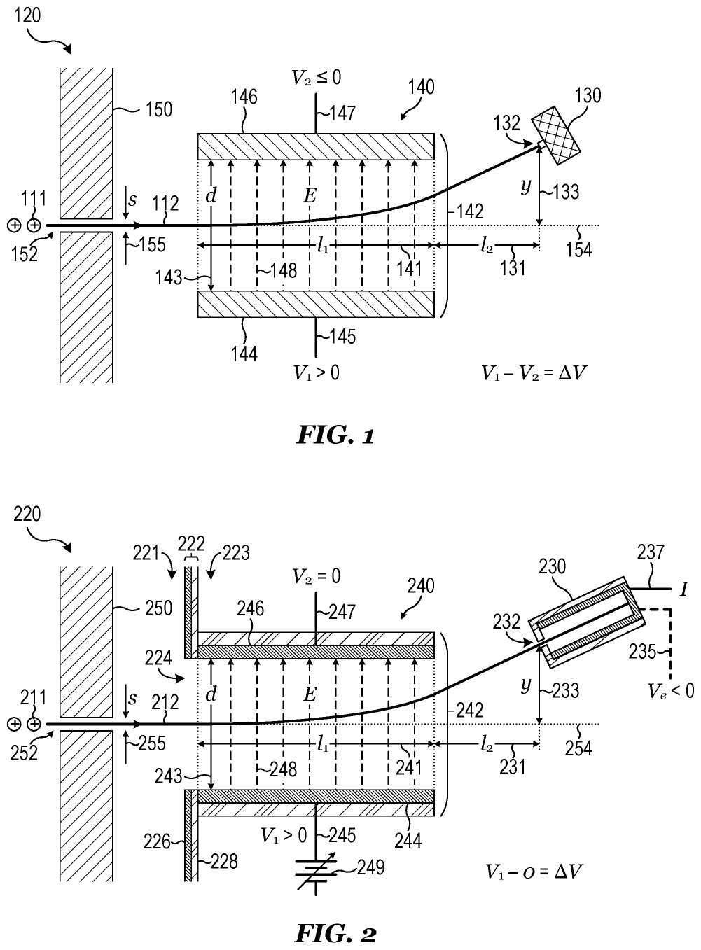

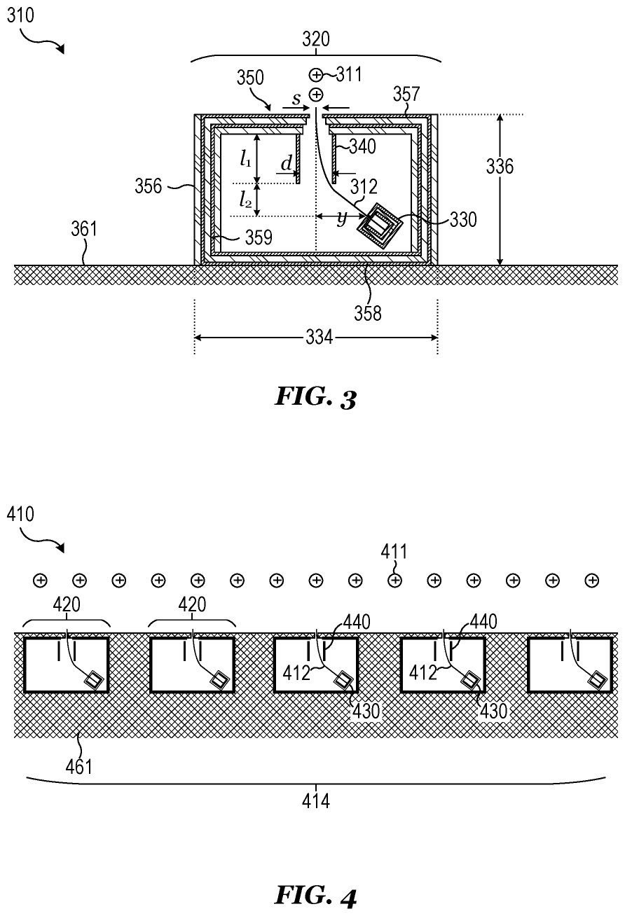

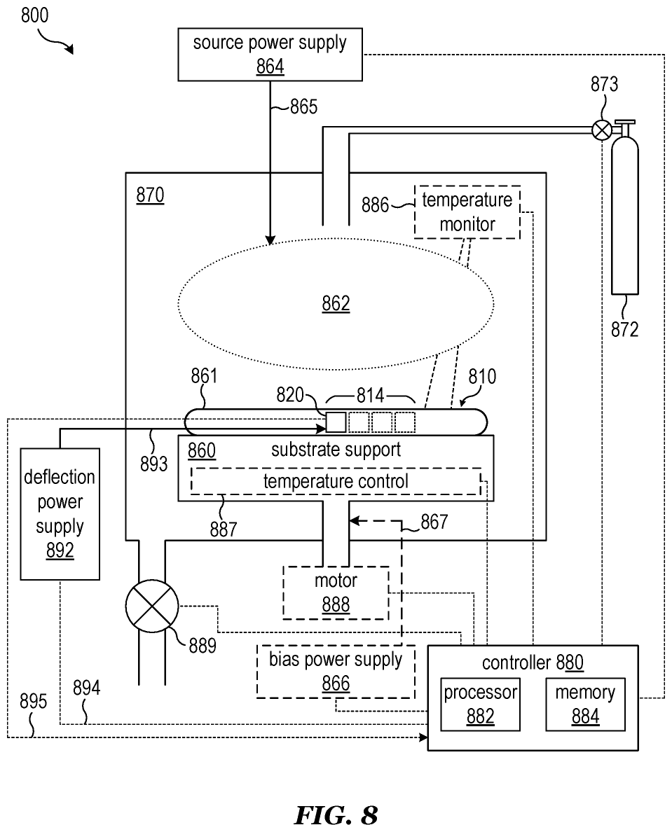

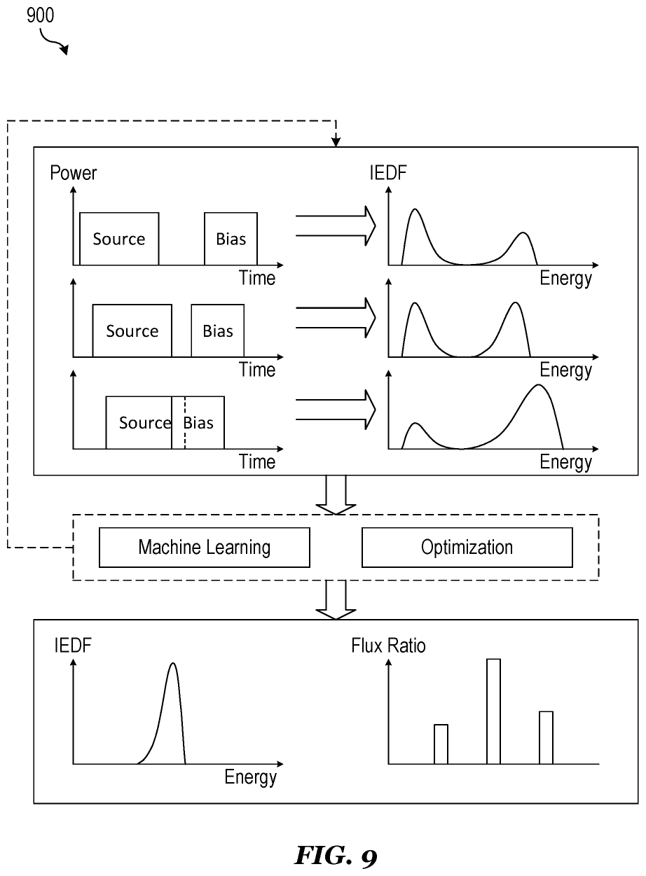

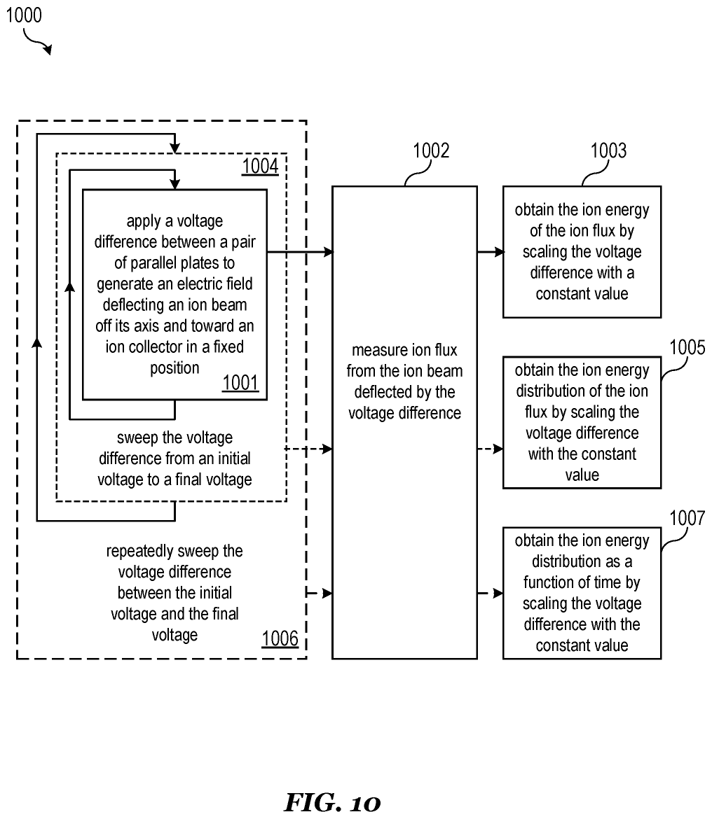

Embodiments provided below describe various apparatuses, systems, and methods for the detection of ion energy and related properties of a plasma, and in particular embodiments, grid-less ion energy detectors that use an ion deflector with a pair of parallel plates to enable grid-less detection of ion energy at a fixed ion collector. The following description describes the embodiments. FIG. 1 is used to describe an example grid-less ion energy detector. Another grid-less ion energy detector is described using FIG. 2. An example ion energy detection system that includes a grid-less ion energy detector is described using FIG. 3. Four more example ion energy detection systems that include arrays of grid-less ion energy detectors are described using FIGS. 4-7. An example plasma system that includes one or more grid-less ion energy detectors is described using FIG. 8 while FIG. 9 is used to describe a flowchart of an example method of process optimization using one or more grid-less ion energy detectors. FIG. 10 is used to describe an example method of measuring ion energy of a plasma.

FIG. 1 illustrates an example ion energy detector that uses an ion deflector with a pair of parallel plates to enable grid-less detection of ion energy at a fixed ion collector in accordance with embodiments of the invention.

Referring to FIG. 1, an ion energy detector 120 includes an ion deflector 140 configured to deflect an ion beam 112 generated from ions 111 (e.g., from a plasma) by an aperture 152 of an ion shield 150 toward an ion collector 130 at a fixed position 132 offset from an aperture axis 154 (e.g., also the axis of the ion beam 112). The ion deflector 140 includes a pair of parallel plates 142 which are shown here as a first plate 144 and a second plate 146. The ion shield 150 is configured to isolate the ion deflector 140 and the ion collector 130 from the ions 111 so that only ions passing through the aperture 152 and forming the ion beam 112 (behind the ion shield 150) reach the ion collector 130.

The ion energy detector 120 is a grid-less ion energy detector (having no grid between ions 111 and an aperture of the ion shield 150 as well as having no grid between the aperture 152 and the ion collector 130 so that the ion beam 112 travels unobstructed from the ions 111 to the ion collector 130, the ion deflector 140 not being a grid). Advantageously, the ion energy detector 120 may be immune to arcing and sputter damage associated with conventional ion energy detectors that use multiple closely-spaced grids. Furthermore, the ion energy detector 120 does not use moving parts during the detection process.

The first plate 144 is coupled to a first voltage 145 that is greater than zero (V₁>0) in this configuration (because the ions 111 are positive and the ion collector 130 is offset from the aperture axis 154 in the direction of the second plate 146).

The second plate 146 is coupled to a second voltage 147 that is less than or equal to zero (V₂≤0) in this configuration (ensuring that the voltage difference (V₁−V₂=ΔV) between the pair of parallel plates 142 results in an electric field 148 (denoted by E) that points in the appropriate direction for the ions 111 and the ion collector 130. Of course, if the sign of the ions 111 is negative or the location of the ion collector 130 is moved, the particular voltages on the two plates may be applied in a different arrangement configured to deflect the ions 111 toward the ion collector 130.

The electric field 148 generated between the pair of parallel plates 142 is configured to deflect the ion beam 112 toward the ion collector 130. The geometry of the ion energy detector 120 then determines a constant scaling value for converting E (from the applied voltage difference ΔV) to measured ion energy. For example, the kinetic energy of each of the ions 111 entering the ion deflector 140 will determine their final position in the ion energy detector 120 so that the ion collector 130 only detects ions within a specific (i.e., narrow) range of ion energies. Additionally, the magnitude of the ion flux of the ion beam 112 actually reaching the ion collector 130 may also depend on other geometric factors such as an aperture diameter 155 (s) of the aperture 152 and the entrance diameter of the ion collector 130 (as well as other considerations).

Specifically, the geometry of the ion energy detector 120 includes a deflector length 141 (l₁), a deflector width 143 (d), a deflector offset 131 (₂), and an axis offset 133 (y) that define the region of the ion energy detector 120 that the ion beam 112 travels through from the moment it enters the electric field 148 until it reaches the fixed position 132 of the ion collector 130. The constant scaling value then is a proportionality constant that depends on the applied voltage difference and the various lengths of the ion energy detector 120. For example, the ion energy can be obtained using Eᵢₒₙ=AeΔV/yd, where A is a function of l₁ and l₂. For this reason, the ion energy measurement of the ion energy detector 120 may be considered a direct measurement of the IED (as opposed to conventional ion energy detectors that require taking the derivative of measured ion current).

While the ion energy detector 120 is measuring the ion energy, the voltage difference (i.e., one or both of the first voltage 145 and the second voltage 147) may be adjusted. For example, the first voltage 145 may be swept between a lower-magnitude voltage to a higher-magnitude voltage to measure the ion flux of the ion beam 112 at a range of ion energies. The voltage difference may also be repeatedly swept between the lower-magnitude and higher-magnitude voltages in order to obtain the IED as a function of time.

FIG. 2 illustrates an example ion energy detector that includes a front plate with a grounded conductive surface and an ion deflector with a pair of parallel plates to enable grid-less detection of ion energy at a fixed Faraday cup in accordance with embodiments of the invention. The ion energy detector of FIG. 2 may be a specific implementation of other ion energy detectors described herein such as the ion energy detector of FIG. 1, for example. Similarly labeled elements may be as previously described.

Referring to FIG. 2, an ion energy detector 220 includes an ion deflector 240 configured to deflect an ion beam 212 generated from ions 211 (e.g., from a plasma) by an aperture 252 of an ion shield 250 toward a Faraday cup 230 (a specific implementation of an ion collector) at a fixed position 232 offset from an aperture axis 254 (e.g., also the axis of the ion beam 212). It should be noted that here and in the following a convention has been adopted for brevity and clarity wherein elements adhering to the pattern [x20] where ‘x’ is the figure number may be related implementations of an ion energy detector in various embodiments. For example, the ion energy detector 220 may be similar to the ion energy detector 120 except as otherwise stated. An analogous convention has also been adopted for other elements as made clear by the use of similar terms in conjunction with the aforementioned numbering system.

In this specific example, a front plate 222 is also included in front of the ion deflector 240 (i.e., anywhere between the ion shield 250 and the ion deflector 240, and with an opening 224 that is coextensive with an entrance of the ion deflector 240 in some embodiments, such as the example shown here). The front plate 222 includes a grounded electrically conductive surface 226 at a front side 221 of the front plate 222 (i.e., toward the source of the ion beam 212, which here is the aperture 252). An electrically insulating surface 228 is included at a back side 223 of the front plate 222, which may be configured to electrically isolate the grounded electrically conductive surface 226 from conductive surfaces of the ion deflector 240. While the front plate 222 is implemented as a separate structure from the ion shield 250 in this embodiment, in other embodiments, the front plate 222 may be part of or in contact with the ion shield 250.

The ion deflector 240 includes a pair of parallel plates 242 implemented as a scan plate 244 and a ground potential 247 in this specific example. The scan plate 244 is coupled to a nonzero voltage 245 that is configured to be adjusted using a variable voltage power supply 249. For example, the nonzero voltage 245 may be swept between a lower-magnitude voltage to a higher-magnitude voltage to measure the ion flux of the ion beam 212 at a range of ion energies. The grounded plate 246 is coupled to a ground potential 247 (which may be a reference potential or earth ground). It should be noted that while in this specific example, the nonzero voltage 245 is a positive voltage (that deflects the ion beam 212 upward in the figure toward the Faraday cup 230), the nonzero voltage 245 could also be negative in some embodiments (and the fixed position 232 could be adjusted accordingly). Moreover, the identities of the scan plate 244 and the grounded plate 246 could be switched in some embodiments.

The voltage difference (here, V₁−0=ΔV=V₁) results in an electric field 248 (denoted as E) generated between the pair of parallel plates 242 that is configured to deflect the ion beam 212 toward the Faraday cup 230. As before, the geometry of the ion energy detector 220 (including a deflector length 241, a deflector width 243, a deflector offset 231, and an axis offset 233) determines a constant scaling value for converting E (from the applied voltage difference) to ion energy. Additionally, the magnitude of the ion flux of the ion beam 212 actually reaching the Faraday cup 230 may also depend on other geometric factors such as an aperture diameter 255 of the aperture 252 and the entrance diameter of the Faraday cup 230 (as well as other considerations).

The ions of the ion beam 212 that enter the Faraday cup 230 are incident on a conductive inner surface and can be detected via an ion current 237 (denoted as I). In some cases secondary electrons can decrease the signal (i.e., decrease the ion current) of the Faraday cup 230. In this example, a negative voltage 235 is applied to a conductive inner surface of Faraday cup 235 (which may mitigate the undesirable effects of secondary electrons). The negative voltage 235 is configured to have substantially no effect (or an easily compensated effect) on the ion signal, such as by applying a relatively small negative voltage (e.g., on the order of tens of volts, such as between about −45 V and about −100 V). The small negative voltage 235 may significantly suppress secondary electrons (which are much lighter than ions) without appreciably affecting the ion flux into the Faraday cup 230.

FIG. 3 illustrates an example ion energy detection system that includes a grid-less ion energy detector disposed on a substrate where the ion energy detector has a conductive front surface at the same electric potential as the substrate surface in accordance with embodiments of the invention. The grid-less ion energy detector of FIG. 3 may be a specific implementation of other ion energy detectors described herein such as the ion energy detector of FIG. 1, for example. Similarly labeled elements may be as previously described.

Referring to FIG. 3, an ion energy detection system 310 includes an ion energy detector 320 disposed on a substrate 361. The substrate 361 may be any type of substrate, such as an insulating, conducting, or semiconducting substrate with one or more layers disposed thereon. One example category of possible substrates would be one of the many types of semiconductor wafer (silicon, silicon-on-insulator, germanium, gallium arsenide, etc.). In this example, the ion energy detector 320 is disposed on a surface of the substrate 361, making both physical and electrical contact with the surface through an outer enclosure surface 358.

In this example, the ion energy detector 320 includes an enclosure 356 that contains an ion collector 330 and an ion deflector 340. The electric potential of the substrate 361 may be electrically coupled to an outer shield surface 357 of an ion shield 350 of the ion energy detector 320 (so that the front of the ion energy detector 320 is at the same electric potential as the surface of the substrate 361). This may facilitate more accurate measurement of the ion energy of ions that would be otherwise incident on the substrate, such as during a plasma process. Additionally, a ground plane 359 may also be included in the enclosure 356.

Like the ion energy detectors discussed thus far, the ion energy detector 320 is a grid-less ion energy detector (having no grid between ions 311 and an aperture of the ion shield 350 generating an ion beam 312 as well as having no grid between the aperture and the ion collector 330 so that the ion beam 312 travels unobstructed from the ions 311 to the ion collector 330, the ion deflector 340 not being a grid).

The ion energy detector 320 is but one example of an implementation of a grid-less ion energy detector that integrates the ion energy detector with a substrate (whether a test substrate or a processing substrate). Of course, other implementations are possible. The dimensions of the ion energy detector 320 may have the advantage of being scalable to fit multiple ion energy detectors (e.g., as a one- or two-dimensional array) on or in the substrate 361. For example, a lateral dimension 334 may be on the order of tens of millimeters (e.g., about 30 mm), or smaller, such as less than 10 mm (one of which is shown here, but a second lateral dimension exists normal to the plane of the figure, which may be the same or different in magnitude than the lateral dimension 334). Similarly, a vertical dimension 336 may be similarly sized, such as on the order of tens of millimeters (e.g., about 25 mm), or smaller, such as less than 10 mm.

Additionally, although the enclosure 356 is shown as symmetric about the ion deflector 340 in this specific example, there is no strict requirement that this be the case. For example, the left side of the enclosure 356 is not necessarily needed for this configuration (since the ion collector 330 remains in a fixed position on the right side of the enclosure 356). The same may be true for the lateral dimension normal to the figure (i.e., going in and out of the page). In various embodiments, these dimensions may be reduced in size relative to the dimension of the enclosure 356 that includes the ion collector 330 (e.g., the ion deflector 340 may be closer to some walls of the enclosure 356 than to the wall nearest the ion collector 330), which may have the advantage of further reducing the lateral footprint of the ion energy detector 320.

FIG. 4 illustrates an example ion energy detection system that includes an array of grid-less ion energy detectors embedded in a substrate in accordance with embodiments of the invention. Each of the array of ion energy detectors of FIG. 4 may be a specific implementation of other ion energy detectors described herein such as the ion energy detector of FIG. 1, for example. Similarly labeled elements may be as previously described.

Referring to FIG. 4, an ion energy detection system 410 includes an array of ion energy detectors 414 with more than one ion energy detector 420 disposed in (as here) or on a test substrate 461. Each ion energy detector 420 of the array of ion energy detectors 414 generates an ion beam 412 that is deflected by an ion deflector 440 toward an ion collector 430 at a respective location of the test substrate 461. That is, each ion energy detector 420 may be a specific implementation of other example ion energy detectors described herein.

In this specific example, the ion shield previously discussed is the substrate material itself, which may have the advantage of ensuring that the region around apertures used to form each ion beam 412 is at the same potential as the surface of the test substrate 461. Connections to each ion energy detector 420 in the test substrate 461 may be integrated into the test substrate 461 or may be made through the top of test substrate 461. Although shown as a two-dimensional array for simplicity, the array of ion energy detectors 414 may also extend in a second direction (i.e., into and/or out of the page) to achieve spatial resolution of ion energy across a two-dimensional surface of the test substrate 461.

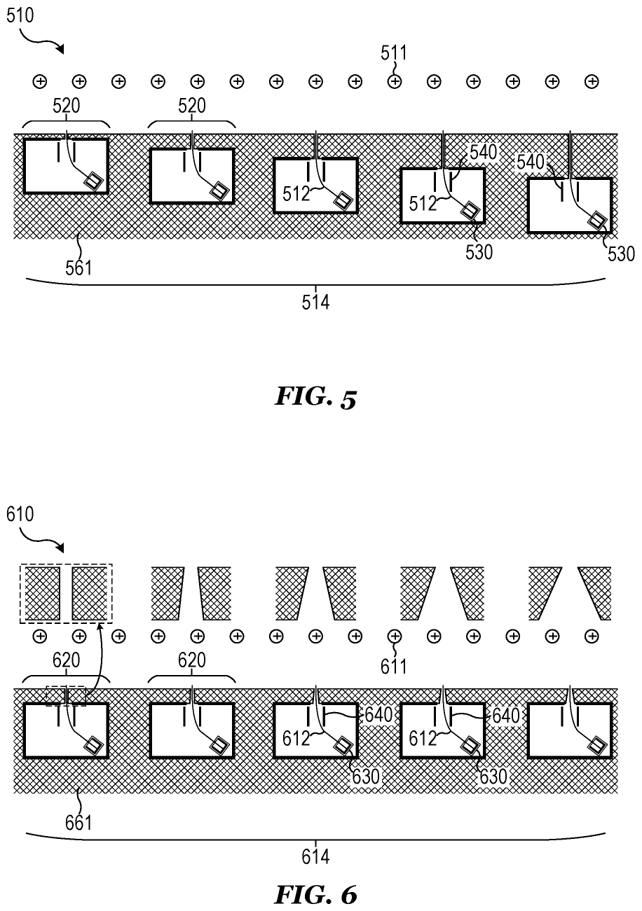

FIG. 5 illustrates an example ion energy detection system that includes an array of grid-less ion energy detectors with ion apertures of different aspect ratios embedded in a substrate in accordance with embodiments of the invention. Each of the array of ion energy detectors of FIG. 5 may be a specific implementation of other ion energy detectors described herein such as the ion energy detector of FIG. 1, for example. Similarly labeled elements may be as previously described.

Referring to FIG. 5, an ion energy detection system 510 includes an array of ion energy detectors 514 with more than one ion energy detector 520 disposed in (as here) or on a test substrate 561. Each ion energy detector 520 of the array of ion energy detectors 514 generates an ion beam 512 that is deflected by an ion deflector 540 toward an ion collector 530 at a respective location of the test substrate 561. The ion energy detection system 510 may be similar to the ion energy detection system 410, except that the aspect ratio of apertures of the array of ion energy detectors 514 may be varied, as schematically shown.

The variation in aspect ratio of the apertures may influence the properties of the ion beams generated in the array of ion energy detectors 514 allowing additional properties to be probed by the ion energy detection system 510. For example, information about the ion conductance of the ions 511 may be obtainable using the array of ion energy detectors 514 with varying aperture aspect ratios. It should also be mentioned that although only five ion energy detectors are shown and the aspect ratio gets progressively higher with only one detector for each specific aspect ratio, this is not a requirement. Indeed (as will be discussed in further detail in the following), the different apertures can be repeated with a pattern allowing the additional quantities (e.g., ion conductance) to also be measured with spatial resolution.

FIG. 6 illustrates an example ion energy detection system that includes an array of grid-less ion energy detectors with ion apertures of different shapes embedded in a substrate in accordance with embodiments of the invention. Each of the array of ion energy detectors of FIG. 6 may be a specific implementation of other ion energy detectors described herein such as the ion energy detector of FIG. 1, for example. Similarly labeled elements may be as previously described.

Referring to FIG. 6, an ion energy detection system 610 includes an array of ion energy detectors 614 with more than one ion energy detector 620 disposed in (as here) or on a test substrate 661. Each ion energy detector 620 of the array of ion energy detectors 614 generates an ion beam 612 that is deflected by an ion deflector 640 toward an ion collector 630 at a respective location of the test substrate 661. The ion energy detection system 610 may be similar to the ion energy detection system 410, except that the shape of apertures of the array of ion energy detectors 614 may be varied, as schematically shown.

As with varying aspect ratio, the variation in the shape of the apertures may influence the properties of the ion beams generated in the array of ion energy detectors 614. Similar to before, information about the ion conductance of the ions 611 may be obtainable using the array of ion energy detectors 614 with varying aperture shapes. The number and pattern of the differently shaped apertures (as well as the type of shapes) may be varied as desired to fit the goals of a given application. Additionally, it is conceivable that varying both the aspect ratio and the shape of the apertures may at times be included in the same test wafer (as well as varying other parameters of the ion energy detectors).

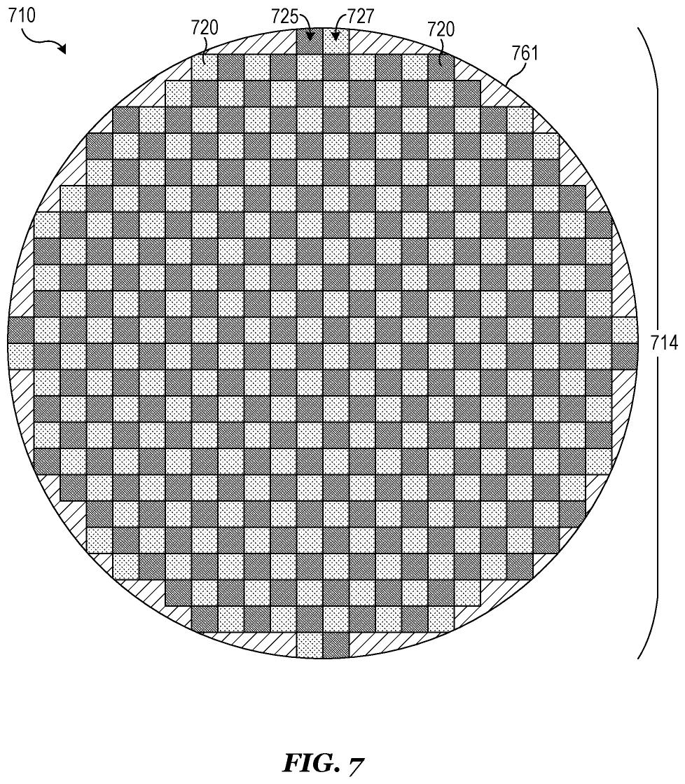

FIG. 7 illustrates an overhead view of an example ion energy detection system that includes an array of ion energy detectors embedded in a substrate in accordance with embodiments of the invention. Each of the array of ion energy detectors of FIG. 7 may be a specific implementation of other ion energy detectors described herein such as the ion energy detector of FIG. 1, for example. Similarly labeled elements may be as previously described.

Referring to FIG. 7, an ion energy detection system 710 includes a test substrate 761 that has an array of ion energy detectors 714 arranged in a pattern across both lateral dimensions of the test substrate 761. Of course, each ion energy detector 720 could be the same in the array of ion energy detectors 714. However, in this specific example, ion energy detectors with a first aperture type 725 (e.g., aperture aspect ratio, aperture shape, etc.) are alternated with ion energy detectors with second aperture type 727. This, may allow for other information, such as ion conductance, to also be resolved with spatial resolution across the test substrate 761 (e.g., with resolution half that of the ion energy, provided the difference in aperture can be correct for in the ion energy measurements).

More than two types may also be included (e.g., five types as shown in previous figures). Further, the size of each ion energy detector 720 in the array of ion energy detectors is provided by way of example only. The actual size may be larger or smaller (e.g., 30+ detectors in a row/column when the lateral dimensions of the detectors are smaller than 10 mm). Additionally, the overhead view of the ion energy detection system 710 may represent an array embedded in the test substrate 761 or an array set brought into contact with a top surface of the test substrate 761 (such as by placing an array structure on the substrate surface).

FIG. 8 illustrates an example plasma system that includes one or more grid-less ion energy detectors and may be used to perform methods of measuring ion energy of a plasma in accordance with embodiments of the invention. Each of the one or more ion energy detectors of FIG. 8 may be a specific implementation of other ion energy detectors described herein such as the ion energy detector of FIG. 1, for example. Similarly labeled elements may be as previously described.

Referring to FIG. 8, a plasma system 800 includes an ion energy detection system 810 that includes at least one ion energy detector 820 disposed within a chamber 870. The ion energy detector 820 uses an ion deflector with a pair of parallel plates to enable grid-less detection of ion energy at a fixed ion collector. That is, the ion deflector is configured to deflect an ion beam produced from a plasma 862 toward the ion collector. The plasma system 800 may also include a substrate support 860 disposed within the chamber 870 and configured to support a substrate 861 (which may be a test substrate configured to measure properties of the plasma, or may be a substrate similar or identical to a substrate to be processed with the plasma during a plasma process, such as a processing wafer). Alternatively, the substrate support 860 may instead be a custom support configured to support the ion energy detector 820 (or multiple ion energy detectors). In various embodiments, the ion energy detector 820 is included as part of an optional ion energy detector array 814, which may be disposed on the surface of the substrate 861 (e.g., when the substrate 861 is a processing substrate) or embedded in the substrate 861 (e.g., when the substrate 861 is a test substrate).

A process gas source 872 (e.g., an etchant gas, precursor gas, etc.) is fluidically coupled to the chamber 870 through one or more valves 873. Additional gas sources and valves may also be included in the plasma system 800. For example, a gas source or sources including additional gases may be included, such as carrier gases, additional reactants and precursors, stabilizers, catalysts and others) may be fluidically coupled to the chamber 870 one or more valves. An exhaust valve 889 is also included to evacuate the chamber 870 during the processes performed therein, such as etching processes, deposition processes, and others as well as during any test processes used to measure plasma parameters such as ion energy, IED, ion conductance, and others.

The chamber 870 may be any suitable chamber capable of containing the plasma 862, such as a plasma etch chamber (e.g., a capacitively coupled plasma (CCP) etch chamber, an inductively coupled plasma (ICP) etch chamber, etc.), a plasma deposition chamber (e.g., a plasma-enhanced chemical vapor deposition (PE-CVD) chamber, a plasma-enhanced atomic layer deposition (PE-ALD) chamber, etc.), and others. The chamber 870 may also be a test chamber used for testing plasma properties (e.g., to determine desirable parameters for a given plasma process). When the chamber 870 is a test chamber, the chamber 870 may have some degree of similarity to chambers used for processing, such as to obtain relevant plasma measurements. In other embodiments, the chamber 870 is a processing chamber, such as an etch chamber, a deposition chamber, or a multipurpose chamber. The substrate support 860 may then be used to support the ion energy detector 820 during testing, a test substrate including the ion energy detector 820, or one or more substrates during processing.

Alternatively, a specialized support may be used for the ion energy detector 820 and a different support may be used to support one or more substrates during processing. Further, the ion energy detector 820 may be included in the chamber 870 in a separate capacity from the substrate support 860 and a substrate being processed so that measurements may be made in situ during a plasma process, whether during process steps or between process steps, continuously or at desired moments of the plasma process.

The plasma system 800 is configured to generate the plasma 862 using a source power supply 864 configured to couple source power 865 to gases in the chamber 870 (e.g., the process gas from the process gas source 872 and any other gases included in the chamber 870). A bias power supply 866 may also be included that is configured to supply bias power 867 to the substrate support 860, such as to accelerate ions in the plasma 862 towards a supported substrate (or the ion energy detector 820), for example.

An optional temperature monitor 886 may also be included to monitor and/or aid in controlling the temperature of the substrate 861 and the environment in the chamber 870. An optional temperature control device 887 (heater, cooler, or combination thereof) may be included to elevate or reduce the temperature of the substrate 861 above/below the equilibrium temperature at the substrate 861 during process steps (although some process steps may be performed at ambient temperatures even when the optional temperature control device 887 is included). An optional motor 888 may also be included to improve process (e.g., etch/deposition) uniformity.

A deflection power supply 892 is configured to supply the ion energy detector 820 with deflection power 893 for the ion deflector. A controller 880 (or a control system including multiple specialized controllers that may also be considered the controller 880) is operatively coupled to the deflection power supply 892, the one or more valves 873, and the source power supply 864, and may be operatively coupled to any of the bias power supply 866, the optional temperature monitor 886, the optional temperature control device 887, the optional motor 888, and the exhaust valve 889. For example, the plasma system 800 may be configured to control the deflection power supply 892 using a deflection signal 894 and receive ion flux measurements from the ion energy detector using an ion flux signal 895.

The controller 880 includes a processor 882 and a memory 884 (i.e., a non-transitory computer-readable medium) that stores a program including instructions that, when executed by the processor 882, perform methods of measuring the ion energy, IED, time-resolved IED, ion conductance, etc. of a plasma (such as a plasma substantially the same as or similar that used for a plasma process, such as an etching process, a deposition process, etc. For example, the memory 884 may have volatile memory (e.g., random access memory (RAM)) and non-volatile memory (e.g., flash memory). Alternatively, the program may be stored in physical memory at a remote location, such as in cloud storage. The processor 882 may be any suitable processor, such as the processor of a microcontroller, a general-purpose processor (such as a central processing unit (CPU), a microprocessor, a field-programmable gate array (FPGA), an application-specific integrated circuit (ASIC), and others.

FIG. 9 illustrates a flowchart of an example method of process optimization using one or more grid-less ion energy detectors in accordance with embodiments of the invention.

Referring to FIG. 9, a method 900 of process optimization using one or more grid-less ion energy detectors may begin with acquiring IED data (e.g., to produce IEDF plots like those qualitatively shown) for different process conditions and parameters. One possible application of varying the timing of source power pulses and bias power pulses (such as in a pulsed plasma etching process or pulse plasma deposition process) is shown here. Of course, while the relative timing of the source pulses and the bias pulses may be important, other timing aspects (and process conditions) may also be varied to produce a large amount of usable IED data for a given process.

Some or all of the potential capabilities of the example ion energy detection systems described herein may be leveraged, including spatial resolution, time-dependent IED measurements, ion conductance measurements, and others. The data may be used to optimize the process and arrive at (for example) an IEDF centered at a single desired energy level and with desired flux ratios (e.g., relative fluxes of various species, such as ions and radicals). Due to the complexity and quantity of the data, machine learning may be utilized during the optimization process as well as multiple iterations of optimization and data acquisition.

FIG. 10 illustrates an example method of measuring ion energy of a plasma in accordance with embodiments of the invention. The method of FIG. 10 may be combined with other methods and performed using the systems and apparatuses as described herein. For example, the method of FIG. 10 may be combined with any of the embodiments of FIGS. 1-9. Although shown in a logical order, the arrangement and numbering of the steps of FIG. 10 are not intended to be limited. The method steps of FIG. 10 may be performed in any suitable order or concurrently with one another as may be apparent to a person of skill in the art.

Referring to FIG. 10, a method 1000 of measuring ion energy includes a step 1001 of applying a voltage difference between a pair of parallel plates to generate an electric field deflecting the ion beam off the axis of the aperture and toward the ion collector. For example, the method 1000 may be performed using a plasma system that includes a chamber configured to contain a plasma. A substrate may be disposed in the chamber (e.g., a substrate similar or identical to that used during a plasma process or a test substrate configured to measure properties of the plasma). An ion energy detector is included (e.g., on the surface of the substrate or embedded within the substrate). The ion energy detector is grid-less (having an ion deflector with a pair of parallel plates and an ion collector at a fixed, off-axis position), and may be similar to any of the example ion energy detectors previously described. A controller may be operatively coupled to the ion energy detector and include a processor configured to execute a program to perform the method 1000.

In a step 1002 the flux from the ion beam deflected by the voltage difference is measured by the ion collector. The ion energy of the ions measured as the ion flux is then obtained in step 1003 by scaling the voltage difference with a constant value. The electric field applies a force to the ions of the ion beam that pass between the pair of parallel plates that is transferred into kinetic energy. Because the generated electric field is related to the voltage difference and can be associated with a particular moment in time (or duration of time), the ion flux measured at the ion collector contains information about the energy of the ions as a function of time. Specifically, the ion energy (or ion energy range) of the ions reaching the ion collector is obtainable using the geometry of the ion energy detector (i.e., the fixed position of the ion collector, the deflection length, etc.) as the constant value to scale the voltage difference and arrive at the ion energy.

The process of measuring the ion energy of the ions measured as the ion flux at a single applied voltage difference may be expanded to include a range of voltages. For example, the method 1000 may include an optional step 1004 of sweeping the voltage difference from an initial voltage to a final voltage. Again, in step 1002, the ion flux is measured as a function of the voltage difference, but this time repeatedly (e.g., continuously or at specific intervals or instances) while sweeping the voltage difference. The result is a data set that includes ion energy values (within a range corresponding to the initial voltage and the final voltage) associated with ion flux (e.g., ion current) values. In an optional step 1005, the IED of the plasma can be found over the ion energy range by scaling the voltage difference with the constant value.

Since the IED is obtained in real-time (or near real-time at a resolution of nanoseconds, for example) using steps 1004, 1002, and 1005 over a time duration defined by the rate that the voltage difference is swept from the initial voltage to the final voltage, it is also possible to obtain the IED of the plasma as a function of time. For this purpose, the method 1000 may include an optional step 1006 of repeatedly sweeping the voltage difference between the initial voltage and the final voltage. As before, the step 1002 of measuring the ion flux as a function of the voltage difference is performed while repeatedly sweeping the voltage difference. In an optional step 1007, the IED as a function of time (e.g., with resolution on the order of hundreds of nanoseconds) can then be obtained by scaling the voltage difference with the constant value.

The grid-less configuration of the ion energy detectors may advantageously enable the detection of ion energies higher than those detectable by conventional ion energy detectors. In various embodiments, the ion energy (or range of ion energies) detectable using the method 1000 is greater than about 10 keV. In some embodiments, the detectable ion energy of the method 1000 is greater than about 15 keV, and may be even higher in other embodiments.

The ion energy detector may be included as part of an array of ion energy detectors in an ion energy detection system of a plasma system. The array of ion energy detectors may have the benefit of providing spatial ion energy information in addition to the possible IED and time-resolved IED information of the method 100. Further, the apertures of the array of ion energy detectors may be same (e.g., to achieve the highest possible spatial resolution) or different (e.g., to all additional measurements to be made, such as ion conductance measurements, with or without spatial resolution).

Example embodiments of the invention are summarized here. Other embodiments can also be understood from the entirety of the specification as well as the claims filed herein.

Example 1. An ion energy detector including: an ion shield including an aperture configured to produce an ion beam from incident ions, the ion beam traveling behind the ion shield along an axis of the aperture; an ion collector disposed in a fixed position behind the ion shield and offset from the axis of the aperture; and an ion deflector including a pair of parallel plates disposed behind the ion shield and configured to generate an electric field to deflect the ion beam off the axis of the aperture and toward the ion collector.

Example 2. The ion energy detector of example 1, further including: a front plate including an opening, a front side including a grounded electrically conductive surface, and a back side including an electrically insulating surface facing the ion deflector, the ion beam traveling through the opening of the front plate before reaching the ion deflector.

Example 3. The ion energy detector of example 2, where the ion shield includes the front plate.

Example 4. The ion energy detector of one of examples 1 to 3, where the ion shield is an enclosure containing the ion collector and the ion deflector.

Example 5. The ion energy detector of one of examples 1 to 4, where the pair of parallel plates includes a first plate configured to be coupled to a ground potential and a second plate configured to be coupled to a nonzero voltage.

Example 6. The ion energy detector of one of examples 1 to 5, where the ion collector is coupled to a negative voltage to suppress secondary electrons.

Example 7. The ion energy detector of one of examples 1 to 6, where the ion collector is a Faraday cup.

Example 8. An ion energy detection system including: a substrate; and an ion energy detector in physical contact with the substrate, the ion energy detector including an enclosure including an ion shield including an outer shield surface and an aperture configured to produce an ion beam from incident ions, the outer shield surface having the same electric potential as the substrate, the ion beam traveling into the enclosure along an axis of the aperture, an ion collector disposed in a fixed position in the enclosure and offset from the axis of the aperture, and an ion deflector including a pair of parallel plates disposed in the enclosure and configured to generate an electric field to deflect the ion beam off the axis of the aperture and toward the ion collector.

Example 9. The ion energy detection system of example 8, where the pair of parallel plates includes a first plate configured to be coupled to a ground potential and a second plate configured to be coupled to a nonzero voltage.

Example 10. The ion energy detection system of example 8, where all spatial dimensions of the enclosure are less than about 30 mm.

Example 11. The ion energy detection system of one of examples 8 and 9, where the enclosure further includes an outer enclosure surface in direct contact with the substrate, the outer enclosure surface being electrically coupled to the outer shield surface.

Example 12. The ion energy detection system of one of example 8 to 11, where the ion energy detector is embedded in the substrate.

Example 13. The ion energy detection system of one of examples 8 to 12, further including: n array of ion energy detectors including the ion energy detector and a plurality of additional ion energy detectors.

Example 14. The ion energy detection system of one of examples 8 to 13, where the ion collector is a Faraday cup.

Example 15. A plasma system including: a chamber configured to contain a plasma; a substrate disposed in the chamber; an ion energy detector in physical contact with the substrate, the ion energy detector including an enclosure including an ion shield including an outer shield surface and an aperture configured to produce an ion beam from the plasma, the outer shield surface having the same electric potential as the substrate, the ion beam traveling into the enclosure along an axis of the aperture, an ion collector disposed in a fixed position in the enclosure and offset from the axis of the aperture, and an ion deflector including a pair of parallel plates disposed in the enclosure; and a controller operatively coupled to the ion energy detector, the controller including a processor and a non-transitory computer-readable medium storing a program including instructions that, when executed by the processor, perform a method of measuring ion energy of the plasma, the method including applying a voltage difference between the pair of parallel plates to generate an electric field deflecting the ion beam off the axis of the aperture and toward the ion collector, measuring ion flux from the ion beam deflected by the voltage difference, and obtaining ion energy of ions of the ion flux by scaling the voltage difference with a constant value.

Example 16. The plasma system of example 15, where the program includes further instructions for sweeping the voltage difference from an initial voltage to a final voltage, measuring the ion flux as a function of the voltage difference while sweeping the voltage difference, and obtaining an ion energy distribution of the plasma by scaling the voltage difference with the constant value.

Example 17. The plasma system of example 16, where the program includes further instructions for repeatedly sweeping the voltage difference between the initial voltage and the final voltage, measuring the ion flux as a function of the voltage difference while repeatedly sweeping the voltage difference, and obtaining the ion energy distribution as a function of time by scaling the voltage difference with the constant value.

Example 18. The plasma system of example 17, where the ion energy distribution as a function of time has a resolution on the order of hundreds of nanoseconds.

Example 19. The plasma system of one of examples 15 to 18, where the ion energy is greater than about 10 keV.

Example 20. The plasma system of one of examples 15 to 19, further including: an array of ion energy detectors including the ion energy detector and a plurality of additional ion energy detectors, where the ion energy detectors of the array include apertures shaped differently from one another; and where the program includes further instructions for obtaining ion conductance of the plasma.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. An ion energy detector comprising:
an ion shield comprising an aperture configured to produce an ion beam from incident ions, the ion beam traveling behind the ion shield along an axis of the aperture;
an ion collector disposed in a fixed position behind the ion shield and offset from the axis of the aperture; and
an ion deflector comprising a pair of parallel plates disposed behind the ion shield and configured to generate an electric field to deflect the ion beam off the axis of the aperture and toward the ion collector.

2. The ion energy detector of claim 1, further comprising:
a front plate comprising an opening, a front side comprising a grounded electrically conductive surface, and a back side comprising an electrically insulating surface facing the ion deflector, the ion beam traveling through the opening of the front plate before reaching the ion deflector.

3. The ion energy detector of claim 2, wherein the ion shield comprises the front plate.

4. The ion energy detector of claim 1, wherein the ion shield is an enclosure containing the ion collector and the ion deflector.

5. The ion energy detector of claim 1, wherein the pair of parallel plates comprises a first plate configured to be coupled to a ground potential and a second plate configured to be coupled to a nonzero voltage.

6. The ion energy detector of claim 1, wherein the ion collector is coupled to a negative voltage to suppress secondary electrons.

7. The ion energy detector of claim 1, wherein the ion collector is a Faraday cup.

8. An ion energy detection system comprising:
a substrate; and
an ion energy detector in physical contact with the substrate, the ion energy detector comprising
an enclosure comprising an ion shield comprising an outer shield surface and an aperture configured to produce an ion beam from incident ions, the outer shield surface having the same electric potential as the substrate, the ion beam traveling into the enclosure along an axis of the aperture,
an ion collector disposed in a fixed position in the enclosure and offset from the axis of the aperture, and
an ion deflector comprising a pair of parallel plates disposed in the enclosure and configured to generate an electric field to deflect the ion beam off the axis of the aperture and toward the ion collector.

9. The ion energy detection system of claim 8, wherein the pair of parallel plates comprises a first plate configured to be coupled to a ground potential and a second plate configured to be coupled to a nonzero voltage.

10. The ion energy detection system of claim 8, wherein all spatial dimensions of the enclosure are less than about 30 mm.

11. The ion energy detection system of claim 8, wherein the enclosure further comprises an outer enclosure surface in direct contact with the substrate, the outer enclosure surface being electrically coupled to the outer shield surface.

12. The ion energy detection system of claim 8, wherein the ion energy detector is embedded in the substrate.

13. The ion energy detection system of claim 8, further comprising:
an array of ion energy detectors comprising the ion energy detector and a plurality of additional ion energy detectors.

14. The ion energy detection system of claim 8, wherein the ion collector is a Faraday cup.

15. A plasma system comprising:
a chamber configured to contain a plasma;
a substrate disposed in the chamber;
an ion energy detector in physical contact with the substrate, the ion energy detector comprising
an enclosure comprising an ion shield comprising an outer shield surface and an aperture configured to produce an ion beam from the plasma, the outer shield surface having the same electric potential as the substrate, the ion beam traveling into the enclosure along an axis of the aperture,
an ion collector disposed in a fixed position in the enclosure and offset from the axis of the aperture, and
an ion deflector comprising a pair of parallel plates disposed in the enclosure; and
a controller operatively coupled to the ion energy detector, the controller comprising a processor and a non-transitory computer-readable medium storing a program including instructions that, when executed by the processor, perform a method of measuring ion energy of the plasma, the method comprising
applying a voltage difference between the pair of parallel plates to generate an electric field deflecting the ion beam off the axis of the aperture and toward the ion collector,
measuring ion flux from the ion beam deflected by the voltage difference, and
obtaining ion energy of ions of the ion flux by scaling the voltage difference with a constant value.

16. The plasma system of claim 15, wherein the program includes further instructions for
sweeping the voltage difference from an initial voltage to a final voltage,
measuring the ion flux as a function of the voltage difference while sweeping the voltage difference, and
obtaining an ion energy distribution of the plasma by scaling the voltage difference with the constant value.

17. The plasma system of claim 16, wherein the program includes further instructions for
repeatedly sweeping the voltage difference between the initial voltage and the final voltage,
measuring the ion flux as a function of the voltage difference while repeatedly sweeping the voltage difference, and
obtaining the ion energy distribution as a function of time by scaling the voltage difference with the constant value.

18. The plasma system of claim 17, wherein the ion energy distribution as a function of time has a resolution on the order of hundreds of nanoseconds.

19. The plasma system of claim 15, wherein the ion energy is greater than about 10 keV.

20. The plasma system of claim 15, further comprising:
an array of ion energy detectors comprising the ion energy detector and a plurality of additional ion energy detectors, wherein the ion energy detectors of the array comprise apertures shaped differently from one another; and
wherein the program includes further instructions for obtaining ion conductance of the plasma.
